(19) United States
(12) Patent Application Publication
(10) Pub. No.: US 2012/0293193 A1
(43) Pub. Date: Nov. 22, 2012

(54) WATER DETECTING APPARATUS

(76) Inventors: Chia-Zen Sheu, New Taipei City (TW); Chia-Min Tsai, New Taipei City (TW)

(21) Appl. No.: 13/287,139

(22) Filed: Nov. 2, 2011

(30) Foreign Application Priority Data
May 17, 2011 (TW) 100117200

(51) Int. Cl. G01R 27/08

(52) U.S. Cl. 324/694

(57) ABSTRACT

A water detecting apparatus, which comprises: at least one close loop circuit; and a water detecting circuit, for detecting if a resistance value for the close loop circuit is a predetermined value, to determine if any water exists on the close loop circuit.

### BACKGROUND OF THE INVENTION

1. Field of the Invention

The present invention relates to a water detecting apparatus, and particularly relates to a water detecting apparatus utilizing a close loop circuit.

2. Description of the Prior Art

Circuit short problem may easily occur due to the existence of water. Accordingly, a water detecting apparatus is provided to some electronic apparatuses to detect if water exists in the electronic apparatuses. FIG. 1 is a circuit diagram depicting a prior art water detecting apparatus 100. As shown in FIG. 1, the prior art water detecting apparatus 100 utilizes an open loop circuit 103 to detect water. The water resistance 105 does not exist if the open loop circuit 103 has no water thereon. Accordingly, the open loop circuit 103 is in an open state, and the resistance that the comparator 101 detects from the input terminal 107 is infinite. Oppositely, the water resistance 105 exists if the open loop circuit 103 has water thereon. Accordingly, the open loop circuit 103 is not an open state, and the resistance that the comparator 101 detects from the input terminal 107 is not infinite. By this way, a comparing result CR is output from the comparator 101 to inform other devices the existence of water.

However, an open loop circuit may have the issue of non-sensitive response. For example, large resistance may be wrongly determined to be infinite resistance. Accordingly, such circuit structure does not meet the requirement of modern electronic apparatuses.

### SUMMARY OF THE INVENTION

Therefore, one objective of the invention is to provide a water detecting apparatus and a water detecting method with better sensitivity.

One embodiment of the invention is to provide a water detecting apparatus, which comprises: at least one close loop circuit; and a water detecting circuit, for detecting if a resistance value for the close loop circuit is a predetermined value, to determine if any water exists on the close loop circuit.

Another embodiment of the invention is to provide a water detecting method for a water detecting apparatus, which comprises: detecting resistance value of the close loop circuit; and detecting if the resistance value is a predetermined value, to determine if any water exists on the close loop circuit.

In view of above-mentioned embodiments, the water is detected based on if the resistance value is a predetermined value rather than if the resistance value is infinite, such that the prior art detecting circuit sensitivity issue can be avoided. Besides, the circuit design flexibility can be increased since the conductive line distance, coil density, number and shape for the close loop circuit can be changed according to different requirements.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram depicting a prior art water detecting apparatus.

FIG. 2-FIG. 6 are circuit diagrams depicting the water detecting apparatuses according to first-fifth embodiments of the invention.

FIG. 7 is a flow chart depicting the water detecting method according to first-fifth embodiments of the invention.

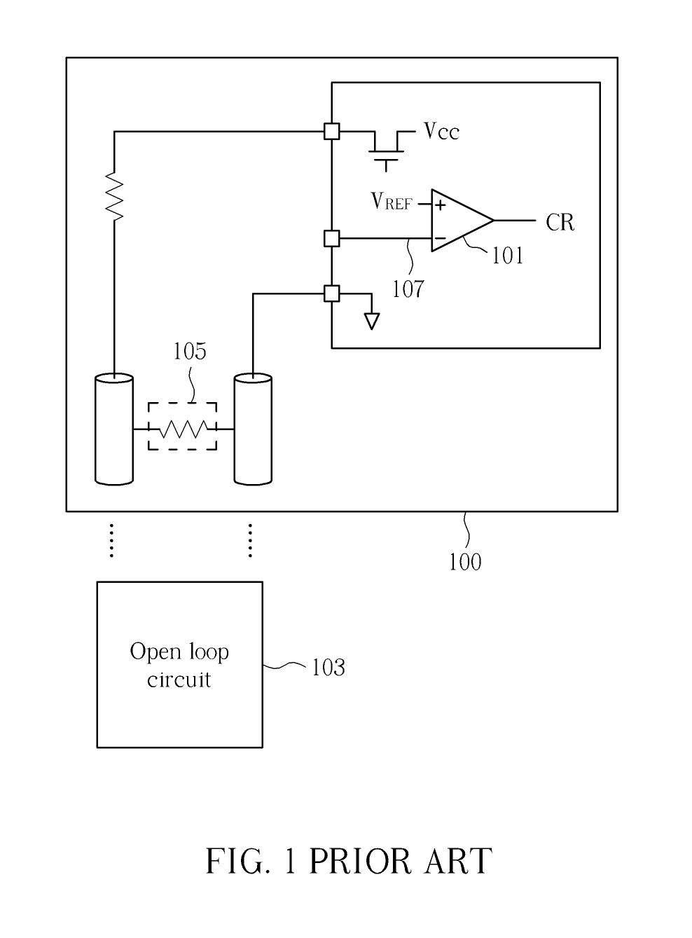

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function.

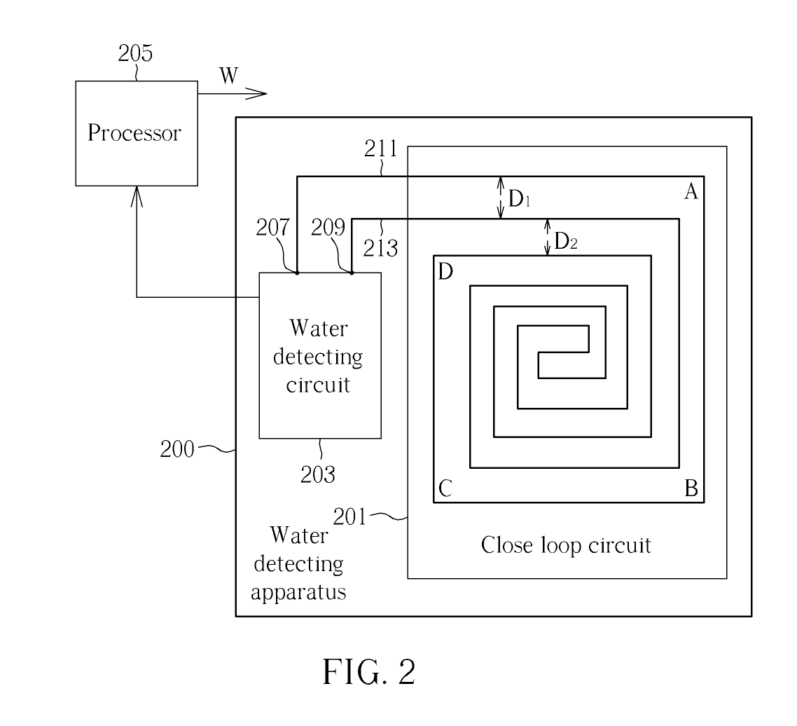

FIG. 2-FIG. 6 respectively depicts water detecting apparatuses according to first to five embodiments of the invention.

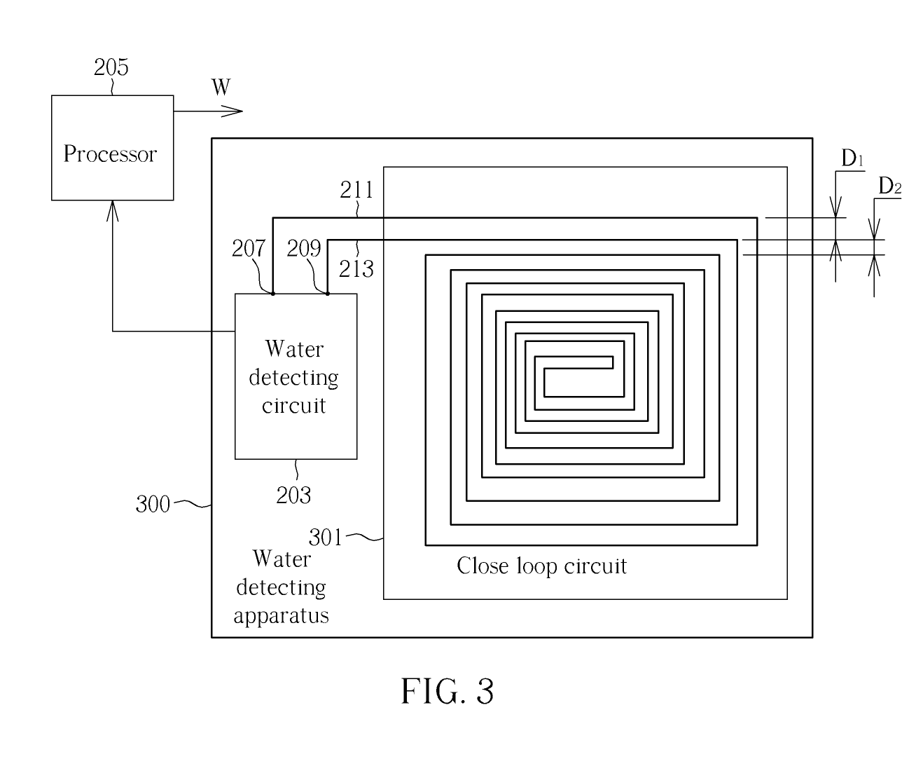

The close loop circuit shown in the embodiment in FIG. 2 and the second embodiment in FIG. 3 include similar structures but include different coil densities. As shown in the first embodiment of FIG. 2, the water detecting apparatus 200 includes a close loop circuit 201 and a water detecting circuit 203. The water detecting circuit 203 detects a resistance value of the close loop circuit 201 and determines if any water exists on the close loop circuit 201 according to if a resistance value for the close loop circuit 201 is a predetermined value or not. That is, if no water exists on the close loop circuit 201, the water detecting circuit 203 will detect that the resistance value for the close loop circuit 201 is a constant value. However, the resistance value for the close loop circuit 201 changes if any water exists on the close loop circuit 201. Accordingly, the existence of water can be detected according to the resistance value of the close loop circuit 201.

In the first embodiment, the close loop circuit 201 includes coils comprising a first part 211 and a second part of a conductive line. The first part 211 and the second part 213 are respectively coupled to the connection points 207 and 209. It should be noted that the first part 211 and the second part 213 can belong to the same conductive line. Naming the two parts to “first” and “second” is for the convenience of description, but does not mean that they are independent. Besides, in this embodiment, if the water detecting circuit 203 detects any water exists on the close loop circuit 201 (i.e. detecting resistance variation of the close loop circuit 201), it can inform the processor 205 such situation. Then, the processor 205 sends an informing message W to perform following operations (ex. heating, drying or power off).

The sensitivity of the water detecting apparatus 200 can be adjusted according to a distance D₁ of the first part and the second part, or depending on coil density related with a distance D₂ for the second part 203 itself. For example, in the second embodiment shown in FIG. 3, the distance D₁ of the close loop circuit 301 is smaller than which of the close loop circuit 201 shown in FIG. 2. Also, the coil density of the close loop circuit 301 shown in FIG. 3 is larger than which of the close loop circuit 201 shown in FIG. 2. Accordingly, the water amount that will cause resistance variation to the close loop circuit 201 is more than which for the close loop circuit 301. Therefore, the sensitivity for the water detecting apparatus 300 is better than which of the water detecting apparatus 200. Besides the consideration for sensitivity, D₁ and D₂ can be adjusted corresponding to different processes and cost. Furthermore, when the first part 211 is parallel with the second part 213, the distance D₁ can be designed to maintain a constant value. By this way, the convenience and stability of the close loop circuit can be increased.

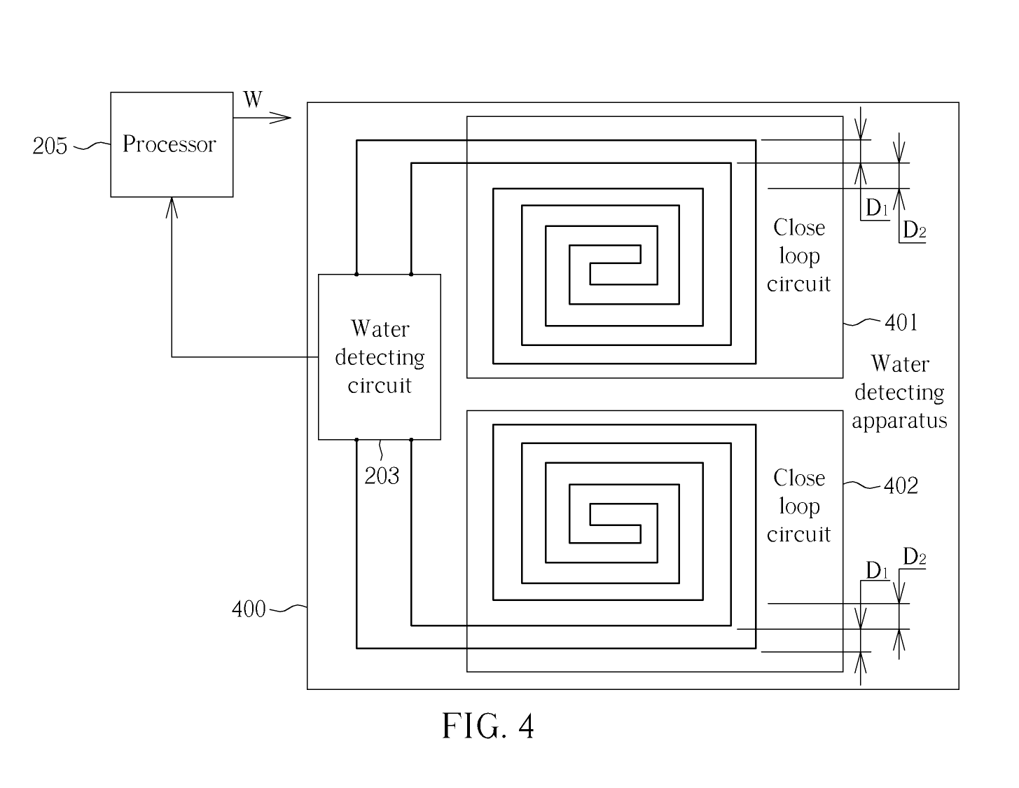

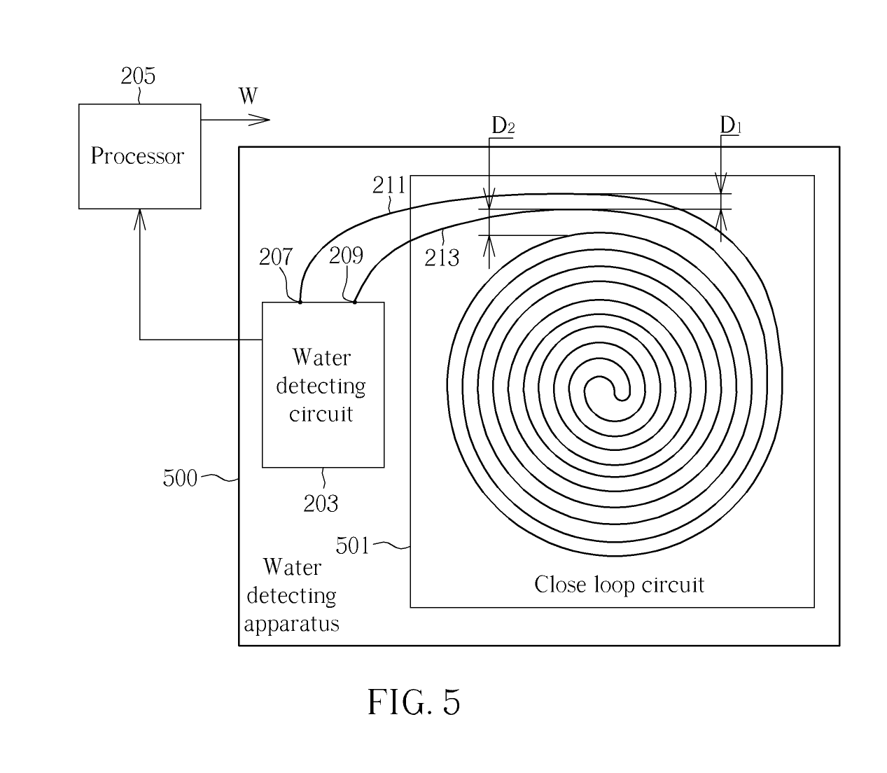

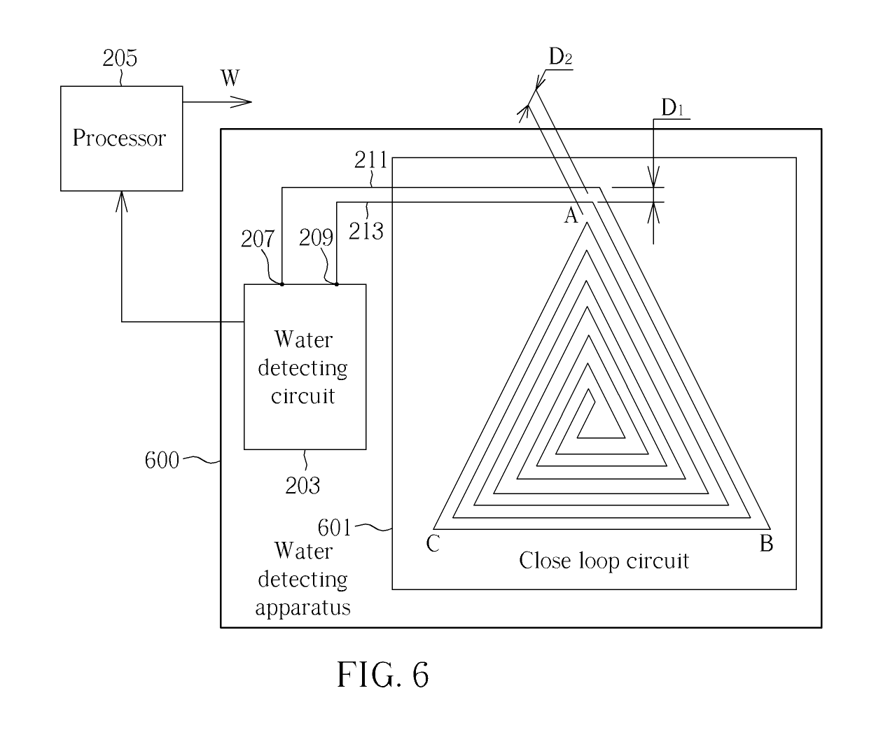

Besides the above-mentioned variation for D₁ and D₂, structures and numbers for the close loop circuit of the water detecting apparatus can be different from which of the first embodiment shown in FIG. 2 and the second embodiment shown in FIG. 3. The third embodiment depicted in FIG. 4, the fourth embodiment depicted in FIG. 5, and the fifth embodiment depicted in FIG. 6 disclose such structures. For example, in the third embodiment shown in FIG. 4, the water detecting apparatus 400 includes a plurality of close loop circuits 401 and 402. Thereby the close loop circuits 401 and 402 can be provided in different locations of the electronic apparatus to detect if any water exists on different parts, thus the reliability is improved.

Alternatively, the fourth embodiment shown in FIG. 5 discloses that the close loop circuit 501 is in a spiral shape (or called a circle shape). Besides, the fifth embodiment shown in FIG. 6 discloses that the close loop circuit 601 is in a triangle shape. That is, in the fourth embodiment shown in FIG. 5, the coils of the close loop circuit 501 include no curved portions, but in the fifth embodiment in FIG. 6, the coils of the close loop circuit 501 include a plurality of curved portions A,B,C. Accordingly, the close loop circuit in the water detecting apparatus according to the invention can be summarized as: including a coil which can be in a spiral shape or a circle shape such as the fourth embodiment shown in FIG. 5, or includes a plurality of curved portions such as the first embodiment shown in FIG. 2 and the fifth embodiment shown in FIG. 6. Such variation should also be included in the scope of the invention.

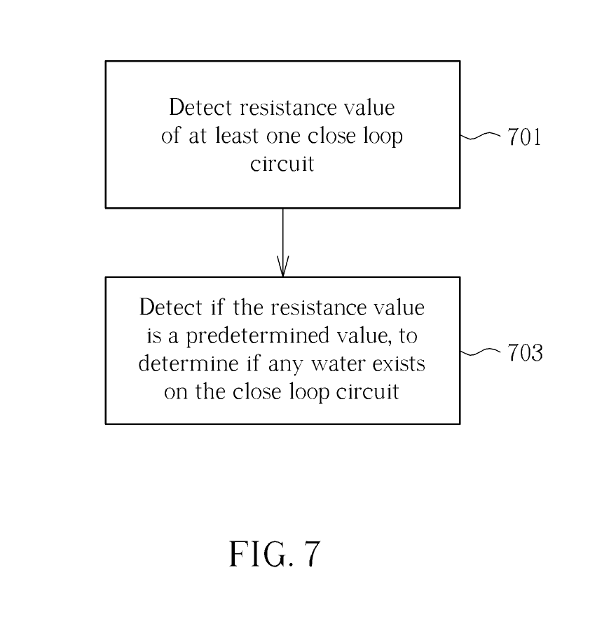

In view of the above-mentioned first to fifth embodiments, the water detecting method shown in FIG. 7 can be acquired. The following steps are included:

Step 701

Detect resistance value of at least one close loop circuit.

Step 703

Detect if the resistance value is a predetermined value, to determine if any water exists on the close loop circuit.

Other detail steps can be acquired according to the above-mentioned first to fifth embodiments, thus are omitted for brevity here.

In view of above-mentioned embodiments, the water is detected based on if the resistance value is a predetermined value rather than if the resistance value is infinite, such that the prior art detecting circuit sensitivity issue can be avoided. Besides, the circuit design flexibility can be increased since the conductive line distance, coil density, number and shape for the close loop circuit can be changed according to different requirements.

Those skilled in the art will readily observe that numerous modifications and alterations of the device and method may be made while retaining the teachings of the invention.

What is claimed is:

1. A water detecting apparatus, comprising:
at least one close loop circuit; and
a water detecting circuit, for detecting if a resistance value for the close loop circuit is a predetermined value, to determine if any water exists on the close loop circuit.

2. The water detecting apparatus of claim 1, wherein the water detecting circuit includes a first connection point and a second connection point, where the close loop circuit includes a coil, and a first part and a second part of a conductive line for the coil are respectively coupled to the first connection point and the second connection point.

3. The water detecting apparatus of claim 2, wherein distances between the first part and the second part are the same, when the first part is parallel to the second part.

4. The water detecting apparatus of claim 2, wherein the coil includes at least one curved portion.

5. The water detecting apparatus of claim 2, wherein sensitivity degree of the water detecting apparatus is determined by distribution density of the coil or a distance between the first part and the second part.

6. A water detecting method for a water detecting apparatus, comprising:
detecting resistance value of the close loop circuit; and
detecting if the resistance value is a predetermined value, to determine if any water exists on the close loop circuit.

7. The water detecting method of claim 6, wherein the water detecting apparatus includes a water detecting apparatus, where the water detecting circuit includes a first connection point and a second connection point, where the close loop circuit includes a coil, and a first part and a second part of a conductive line for the coil are respectively coupled to the first connection point and the second connection point.

8. The water detecting method of claim 7, wherein distances between the first part and the second part are the same, when the first part is parallel to the second part.

9. The water detecting method of claim 7, wherein the coil includes at least one curved portion.

10. The water detecting method of claim 7, wherein sensitivity degree of the water detecting apparatus is determined by distribution density of the coil or a distance between the first part and the second part.
